(19) United States
(12) Patent Application Publication
(10) Pub. No.: US 2015/0187919 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: In Hyuk SONG, Suwon-Si (KR); Dong Soo SEO, Suwon-Si (KR); Kyu Hyun MO, Suwon-Si (KR); Chang Su JANG, Suwon-Si (KR); Jae Hoon PARK, Suwon-Si (KR)

(73) Assignee: SAMSUNG ELECTRO-MECHANICS CO., LTD., Suwon-Si (KR)

(21) Appl. No.: 14/221,972

(22) Filed: Mar. 21, 2014

(30) Foreign Application Priority Data
Jan. 2, 2014 (KR) 10-2014-0000243

(51) Int. Cl. H01L 29/739; H01L 29/06

(52) U.S. Cl. CPC H01L 29/7397; H01L 29/0696

(57) ABSTRACT

A provided a power semiconductor device may include: a first semiconductor region of a first conductive type; a second semiconductor region of a second conductive type formed on the first semiconductor region; a plurality of trench gates formed to penetrate through the second semiconductor region and lengthily formed in one direction; and a third semiconductor region of the first conductive type formed on the second semiconductor region, formed at least partially in a length direction between the plurality of trench gates, and formed to contact one side of an adjacent trench gate in a width direction.

### CROSS-REFERENCE TO RELATED APPLICATION

This application claims the benefit of Korean Patent Application No. 10-2014-0000243 filed on Jan. 2, 2014, with the Korean Intellectual Property Office, the disclosure of which is incorporated herein by reference.

### BACKGROUND

The present disclosure relates to a power semiconductor device.

An insulated gate bipolar transistor (IGBT) refers to a transistor having a bipolar structure as a result of manufacturing a gate using a metal oxide semiconductor (MOS) and forming a p-type collector layer on a rear surface of the transistor.

After a power metal oxide semiconductor field effect transistor (MOSFET) according to the related art was developed, the MOSFET has been used in fields requiring fast switching characteristics.

However, due to a structural limitation of the MOSFET, a bipolar transistor, a thyristor, gate turn-off thyristors (GTOs), and the like, have been used in fields requiring a high voltage.

Since the IGBT is characterized by low forward voltage loss and fast switching speed, it has been widely used for fields which are impossible to implement with the existing thyristor, bipolar transistor, metal oxide semiconductor field effect transistor (MOSFET), and the like.

Describing an operation principle of the IGBT, in the case in which an IGBT element is turned on, a higher voltage is applied to an anode thereof than to a cathode thereof, and in the case in which the voltage higher than a threshold voltage of the element is applied to a gate electrode, polarity of a surface of a p-type body region located at a lower end of the gate electrode is reversed to thereby form an n-type channel.

Electron current injected into a drift region through a channel induces an injection of a hole current from a high density p-type collector layer located at a lower portion of the IGBT element, similar to a base current of the bipolar transistor.

Due to a high concentration injection of the minority carriers, a conductivity modulation phenomenon occurs in which conductivity in the drift region is increased by ten to a hundred times.

Unlike the MOSFET, since the IGBT has a highly reduced resistance component in the drift region due to conductivity modulation, it may be used at a very high voltage.

The current flowing into the cathode is divided into the electron current flowing through the channel and the hole current flowing through a junction between the p-type body and an n-type drift region.

Unlike the MOSFET, since the IGBT has a p-n-p structure between the anode and the cathode due to the structure of a substrate, it does not have a diode embedded therein, such that it needs a separate diode connected thereto in anti-parallel.

The main goals of a technology development of the above-mentioned IGBT are to maintain a blocking voltage, to decrease conduction loss, and to improve switching characteristics.

Particularly, in order to decrease the conduction loss of the IGBT, an interval between trenches has been formed to be small and the conductivity modulation phenomenon has been significantly increased by forming a hole accumulation layer to thereby derive hole accumulation.

However, in this case, negative gate charge is caused significantly by an increase in capacitance between a gate and a collector.

In the case in which the negative gate charge is increased, current oscillation may be increased in a short circuit test and may destroy the IGBT and a drive IC in severe cases.

### SUMMARY

An exemplary embodiment in the present disclosure may provide a power semiconductor device having an alleviated current oscillation phenomenon.

According to an exemplary embodiment in the present disclosure, a power semiconductor device may include: a first semiconductor region of a first conductive type; a second semiconductor region of a second conductive type disposed on the first semiconductor region; a plurality of trench gates disposed to penetrate through the second semiconductor region and lengthily disposed in one direction; and a third semiconductor region of the first conductive type disposed in the second semiconductor region, disposed at least partially in a length direction between the plurality of trench gates, and disposed to contact one side of an adjacent trench gate in a width direction.

The power semiconductor device may further include a fourth semiconductor region of the second conductive type formed on the second semiconductor region, formed at least partially in the length direction between the plurality of trench gates, formed to contact one side of the adjacent trench gate in the width direction, and formed on a trench gate opposing the trench gate having the third semiconductor region formed thereon in the width direction.

A plurality of third semiconductor regions may be formed in the length direction.

The power semiconductor device may further include a fifth semiconductor region formed between the first semiconductor region and the second semiconductor region and having an impurity concentration higher than that of the first semiconductor region.

According to an exemplary embodiment in the present disclosure, a power semiconductor device may include: a first semiconductor region of a first conductive type; a second semiconductor region of a second conductive type disposed on the first semiconductor region; a plurality of trench gates disposed to penetrate through the second semiconductor region and lengthily disposed in one direction; and a third semiconductor region of the first conductive type disposed in the second semiconductor region, wherein the third semiconductor region is disposed at least partially in a length direction between the plurality of trench gates, disposed to contact one side of an adjacent trench gate in a width direction, and disposed to alternately contact both sides of the trench gate in the length direction.

The power semiconductor device may include a fourth semiconductor region of the second conductive type disposed on the second semiconductor region, disposed at least partially in the length direction between the plurality of trench gates, disposed to contact one side of the adjacent trench gate in the width direction, and disposed on a trench gate opposing the trench gate having the third semiconductor region disposed thereon in the width direction.

According to an exemplary embodiment in the present disclosure, a power semiconductor device may include: a plurality of trench gates lengthily disposed in one direction; a p-type body region disposed between the trench gates; and an n-type first emitter region disposed on the body region and disposed to contact one side of an adjacent trench gate.

The power semiconductor device may further include a p-type second emitter region disposed on the body region and disposed to contact a trench gate different from the trench gate contacting the first emitter region in a width direction.

According to an exemplary embodiment in the present disclosure, a power semiconductor device may include: a plurality of trench gates lengthily disposed in one direction; a p-type body region disposed between the trench gates; and a plurality of n-type first emitter regions disposed on the body region and disposed to alternately contact an adjacent trench gate in a length direction.

The power semiconductor device may further include a p-type second emitter region disposed on the body region and disposed to contact a trench gate different from the trench gate contacting the first emitter region in a width direction.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 schematically illustrates a perspective view of a power semiconductor device according to an exemplary embodiment of the present disclosure;

FIG. 2 schematically illustrates a plan view of a power semiconductor device according to an exemplary embodiment of the present disclosure;

FIG. 3 schematically illustrates a cross-sectional view taken along a line A-A′ of FIG. 2;

FIG. 4 schematically illustrates a perspective view of a power semiconductor device, which further includes a second emitter region, according to an exemplary embodiment of the present disclosure;

FIG. 5 schematically illustrates a perspective view of a power semiconductor device, which further includes a hole accumulation region, according to an exemplary embodiment of the present disclosure;

FIG. 6 schematically illustrates a perspective view of a power semiconductor device according to another exemplary embodiment of the present disclosure;

FIG. 7 schematically illustrates a plan view of a power semiconductor device according to another exemplary embodiment of the present disclosure;

FIG. 8 schematically illustrates a cross-sectional view taken along a line B-B′ of FIG. 7;

FIG. 9 schematically illustrates a cross-sectional view taken along a line C-C′ of FIG. 7;

FIG. 10 schematically illustrates a perspective view of a power semiconductor device, which further includes a second emitter region, according to another exemplary embodiment of the present disclosure; and

FIG. 11 schematically illustrates a perspective view of a power semiconductor device, which further includes a hole accumulation region, according to another exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be implemented by any one of a power MOSFET, an IGBT, several types of thyristors, and those similar to the above-mentioned devices. Most new technologies disclosed herein will be described based on the IGBT. However, several exemplary embodiments of the present disclosure disclosed herein are not limited to the IGBT, and, for example, may overall be applied to different forms of power switch technologies including the power MOSFET and several kinds of thyristors. Further, several exemplary embodiments of the present disclosure are illustrated as those including specific p-type and n-type regions. However, several exemplary embodiments of the present disclosure may also be equally applied to elements having opposite conductive types of several regions disclosed herein.

In addition, the n-type or the p-type used herein may be defined as a first conductive type or a second conductive type. Meanwhile, the first conductive type and the second conductive type refer to conductive types different from each other.

In addition, “positive (+)” generally refers to a high concentration doped state and “negative (−)” refers to a low concentration doped state.

Hereinafter, for clarity of explanation, the first conductive type is represented by the n-type and the second conductive type is represented by the p-type, but they are not limited thereto.

In addition, a first semiconductor region represents a drift region, a second semiconductor region represents a body region, a third semiconductor region represents an emitter region, and a fourth semiconductor region represents a hole accumulation region, but they are not limited thereto.

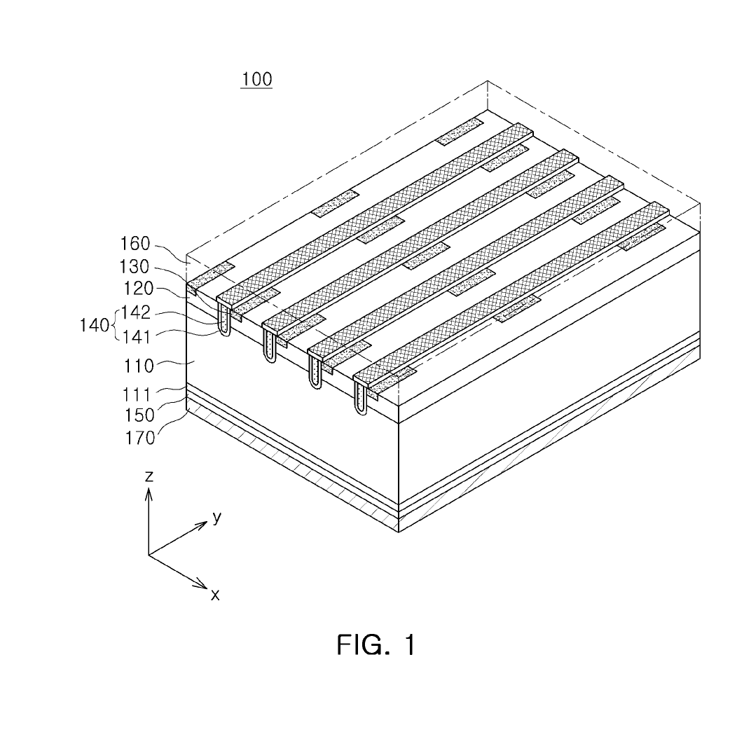

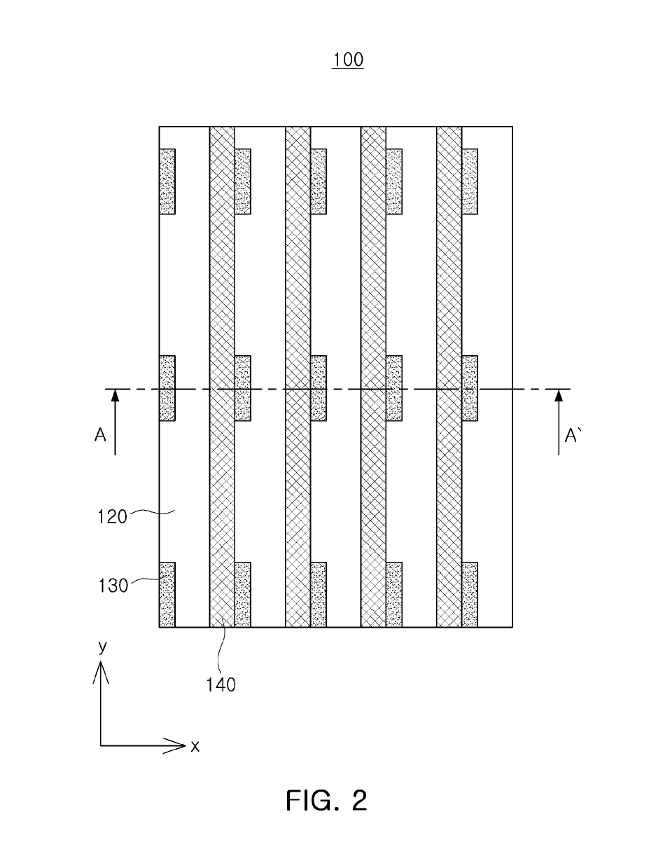

FIG. 1 schematically illustrates a perspective view of a power semiconductor device 100 according to an exemplary embodiment of the present disclosure and FIG. 2 schematically illustrates a plan view of a power semiconductor device 100 according to an exemplary embodiment of the present disclosure.

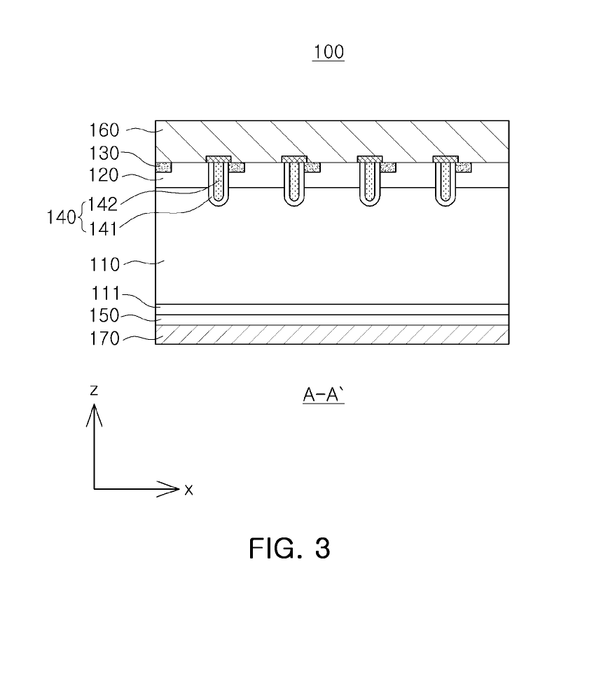

FIG. 3 schematically illustrates a cross-sectional view taken along a line A-A′ of FIG. 2.

A power semiconductor device 100 according to an exemplary embodiment of the present disclosure will be described with reference to FIGS. 1 through 3.

The power semiconductor device 100 according to an exemplary embodiment of the present disclosure may include a collector region 150, a drift region 110, a body region 120, and a first emitter region 130.

The drift region 110 may be formed by injecting an n-type impurity at a low concentration.

Therefore, the drift region 110 may be relatively thick in order to maintain a blocking voltage of the device.

The drift region 110 may further include a buffer region 111 at a lower portion thereof.

The buffer region 111 may be formed by injecting the n-type impurity into a rear surface of the drift region 110.

In the case in which a depletion region of the device is expanded, the buffer region serves to prevent the expansion to thereby maintain the blocking voltage of the device.

Therefore, when the buffer region is formed, the drift region 110 may become thin, whereby the power semiconductor device may be miniaturized.

The body region 120 may be formed by injecting a p-type impurity onto the drift region 110.

Since the body region 120 has a p-type conductive type, it may form a p-n junction with the drift region 110.

The body region 120 may be formed on the drift region 110 so as to have a stripe shape.

The n-type impurity may be injected into an inner side of an upper surface of the body region 120 at a high concentration to form a first emitter region 130.

In addition, a trench gate 140 penetrating through the body region 120 and reaching the drift region 110 may be formed.

The trench gate 140 may be lengthily formed in one direction and be arranged at a predetermined interval in a direction perpendicular to the direction in which the trench gate 140 is lengthily formed.

The trench gate 140 may have a gate insulating layer 141 formed on portions contacting the drift region 110, the body region 120, and the first emitter region 130.

The gate insulating layer 141 may be formed of silicon oxide (SiO₂), but is not limited thereto.

The trench gate 140 may be filled with a conductive material 142.

The conductive material 142 may be a poly-silicon (Poly-Si) or a metal, but is not limited thereto.

The conductive material 142 may be electrically connected to a gate electrode (not shown) to thereby control an operation of the power semiconductor device 100 according to an exemplary embodiment of the present disclosure.

In the case in which a positive voltage is applied to the conductive material 142, a channel C may be formed in the body region 120.

Specifically, in the case in which the positive voltage is applied to the conductive material 142, electrons present in the body region 120 are attracted toward the trench gate 140 and are gathered around the trench gate 140 to thereby form the channel C.

That is, the trench gate 140 attracts the electrons toward the depletion region, in which carriers are not present due to recombination of the electron and the hole by the p-n junction, to form the channel C, thereby allowing a current to be flown.

The collector region 150 may be formed by injecting the p-type impurity at a lower portion of the drift region 110 or of the buffer region.

In the case in which the power semiconductor device is the IGBT, the collector region 150 may provide the hole to the power semiconductor device.

Due to a high concentration injection of the holes which are minority carriers, a conductivity modulation phenomenon may occur in which conductivity in the drift region is increased by tens to hundreds of times.

An emitter metal layer 160 may be formed on an exposed upper surface of the emitter region 130 and the body region 120, and a collector metal layer 170 may be formed on a lower surface of the collector region 150.

The power semiconductor device according to the related art forms an interval between the trench gates to be small in order to decrease conduction loss.

In this case, the conduction loss is decreased, but a current oscillation is intensified, such that noise may be intensified and the power semiconductor device may be destroyed in severe cases.

The current oscillation may mainly be seen in a short circuit test, or the like.

The current oscillation refers to a phenomenon caused by a large amount of holes suddenly moving toward the collector in the case in which the current flows when a high voltage is applied to the collector.

Particularly, in the case in which more holes are accumulated by narrowing the intervals between the trench gates, the accumulated holes disrupt an application of a gate voltage to the trench gate, whereby a backward gate current may instantaneously flow.

The backward gate current refers to a negative gate current.

In the case in which negative gate current flows, a backward voltage drop across a resistor Rg terminal of the gate is induced, whereby a voltage applied to the gate may be decreased.

In the case in which the voltage applied to the gate is decreased, an amount of holes accumulated due to the decreased voltage is decreased, the gate voltage is again increased, and the holes are again accumulated.

That is, the current oscillation may be caused as the gate voltage is repeatedly decreased and increased, as described above.

Particularly, accumulation of the holes may occur more significantly on a lower portion of the trench gate in which the electron current does not flow.

In the case in which the channel is formed in the trench gate to thereby allow the electron current to flow, the electron current moves along the trench gate to which the positive voltage is applied.

The electrons serve as a protection film preventing the accumulated holes from affecting the trench gate.

The power semiconductor device according to the related art has an emitter region which is limitedly formed in order to maintain the blocking voltage of the power semiconductor device.

Therefore, the current oscillation may be generated at a portion in which the electron current does not flow, and increasing the emitter region to solve the above mentioned problem also has a limitation.

Referring to FIG. 2, it may be seen that the power semiconductor device 100 according to an exemplary embodiment of the present disclosure may include the first emitter region 130 formed between the trench gates 140 and formed to contact one side of an adjacent trench gate 140.

That is, the power semiconductor device 100 according to an exemplary embodiment of the present disclosure may include a plurality of trench gates 140 lengthily formed in one direction, a p-type body region 120 formed between the trench gates 140, and an n-type first emitter region 130 formed on the body region 120 and formed to contact one side of the adjacent trench gate 140.

As shown in FIG. 3, it may be seen that the first emitter region 130 is formed to contact one side of the trench gate 140 in a width direction (an x direction).

According to an exemplary embodiment of the present disclosure, in the case in which the first emitter region 130 is formed to contact one side of the trench gate 140, a region in which the current may flow in the width direction may be decreased, but the first emitter region 130 may be increased in a length direction, whereby the region in which the current may flow may be increased.

Taking the power semiconductor device 100 as a whole, since an area of the first emitter region 130 is not changed, the blocking voltage of the power semiconductor device 100 or the current which may flow therein may not be decreased.

Since the power semiconductor device 100 according to an exemplary embodiment of the present disclosure includes the first emitter region 130 formed to contact one side of the trench gate 140 in the width direction, the electrons may flow on a surface of the trench gate 140 having the first emitter region 130 formed thereon.

Therefore, the electrons serve as a protection film preventing the holes from affecting the trench gate 140.

In addition, in the case in which the first emitter region 130 is formed to contact one side of the trench gate 140 in the width direction similar to the power semiconductor device 100 according to an exemplary embodiment of the present disclosure, since the interval between the trench gates 140 is very narrow and the positive voltage is also applied to the trench gate 140 which does not contact the first emitter region 130, the electrons may flow on a surface of the trench gate 140 which does not contact the first emitter region 130.

Therefore, the electrons serve as a protection film preventing the holes from affecting the trench gate 140 even at the lower portion of the trench gate 140 on which the first emitter region 130 is not formed.

That is, the power semiconductor device 100 according to an exemplary embodiment of the present disclosure may significantly decrease the effect of the holes on the trench gate 140 by significantly decreasing a portion in which the first emitter region 130 is not formed in the length direction.

As a result, the current oscillation may be prevented, whereby the noise of the power semiconductor device 100 may be decreased.

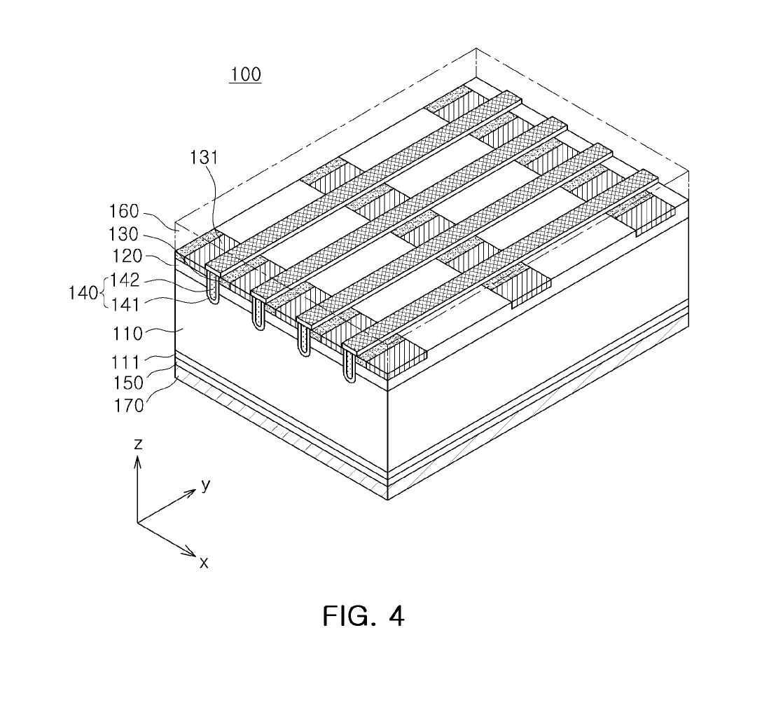

FIG. 4 schematically illustrates a perspective view of a power semiconductor device, further including a second emitter region 131, according to an exemplary embodiment of the present disclosure.

The power semiconductor device according to an exemplary embodiment of the present disclosure may include a parasitic thyristor having a p-n-p-n structure from the bottom.

Once the parasitic thyristor is operated, the IGBT is no longer adjusted by the gate and a significant amount of current flows into the anode and the cathode, whereby excessive heat may be generated from the device and burn the device

A phenomenon in which the parasitic thyristor is turned on is referred to as a latch-up.

Specifically describing a principle in which the latch-up occurs, when the power semiconductor device is operated, the electron current may flow along the channel and the hole current may overpass a junction surface of the body region 120, thereby flowing into a first emitter metal layer 160.

Since the electron current is injected into the drift region 110 of a lower portion of the trench gate 140 along the channel to thereby increase conductivity of the drift region 110, most of hole current may be injected from the body region 120 of a lower portion of the channel and flow into the emitter metal layer 160 through a lower portion of the first emitter region 130.

In the case in which the hole current is increased and a voltage drop across the lower portion of the first emitter region 130 becomes larger than a potential barrier of an interface between the first emitter region 130 and the body region 120, a junction becomes a forward bias, whereby the electrons may be injected from the first emitter region 130 to the body region 120 and a parasitic n-p-n thyristor including an n-type first emitter region 130, a p-type body region 120, and an n-type drift region 110 may be operated.

Therefore, it is necessary to prevent the hole current from being increased at the lower portion of the first emitter region 130.

Referring to FIG. 4, the power semiconductor device 100 according to an exemplary embodiment of the present disclosure may include a p+ type second emitter region 131.

The second emitter region 131 may be formed by injecting a high concentration p-type impurity.

The second emitter region 131 may be at least partially formed in a length direction between a plurality of trench gates 140 and be formed to contact one side of an adjacent trench gate 140 in a width direction.

In addition, the second emitter region 131 may be formed to contact a trench gate 140 opposing the trench gate 140 having the first emitter region 130 formed thereon in the width direction.

That is, the second emitter region 131 may be formed on the body region 120 and be formed to contact a trench gate 140 different from the trench gate 140 having the first emitter region 130 formed thereon in the width direction.

Since the second emitter region 131 is formed by using the high concentration p-type impurity, it may have a very low resistance against the hole current.

Therefore, the hole may flow into the second emitter region 131 and be discharged to the emitter metal layer 160.

That is, the second emitter region 131 may prevent the parasitic thyristor from being operated by preventing the hole from being overpassed to the first emitter region 130.

Therefore, in the case in which the second emitter region 131 is formed, reliability of the power semiconductor device 100 may be improved.

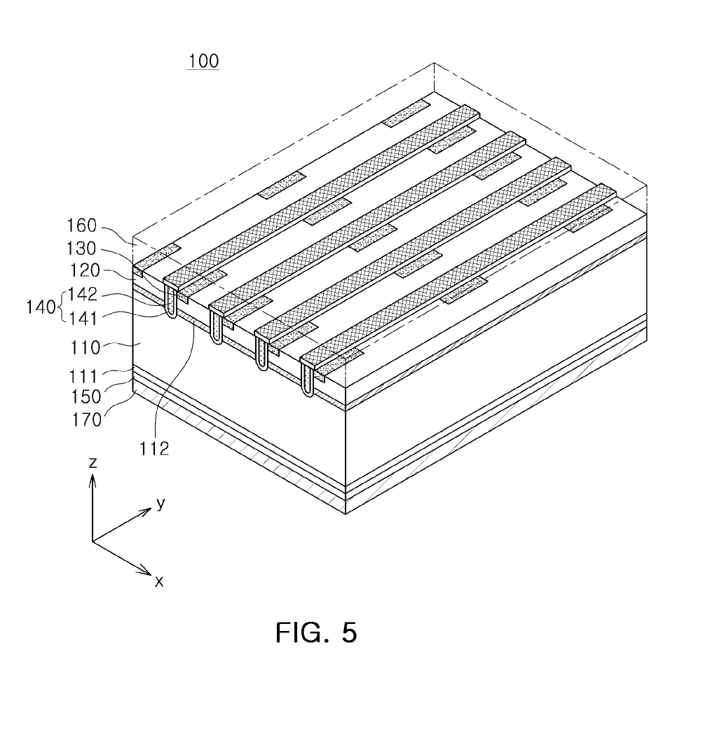

FIG. 5 schematically illustrates a perspective view of a power semiconductor device 100, which further includes a hole accumulation region 112, according to an exemplary embodiment of the present disclosure.

The hole accumulation region 112 may be formed by injecting a high concentration n-type impurity.

In the case in which the hole accumulation region 112 is formed, since the hole is accumulated to thereby significantly increase the conductivity modulation phenomenon, the conduction loss may be decreased.

However, in the case in which only the hole accumulation region 112 is formed, an amount of accumulated holes is increased such that the negative gate current is increased, thereby increasing the noise.

Since the power semiconductor device 100 according to an exemplary embodiment of the present disclosure includes the first emitter region 130 formed to contact one side of the trench gate 140 in the width direction, the electrons may serve as a protection film preventing the holes from affecting the trench gate 140.

That is, the power semiconductor device 100 according to an exemplary embodiment of the present disclosure may significantly decrease the effect of the holes on the trench gate 140 by significantly decreasing a portion in which the first emitter region 130 is not formed in the length direction.

Therefore, the power semiconductor device 100 according to an exemplary embodiment of the present disclosure may decrease the conduction loss by the hole accumulation region 112 and prevent the current oscillation, thereby decreasing the noise of the power semiconductor device 100.

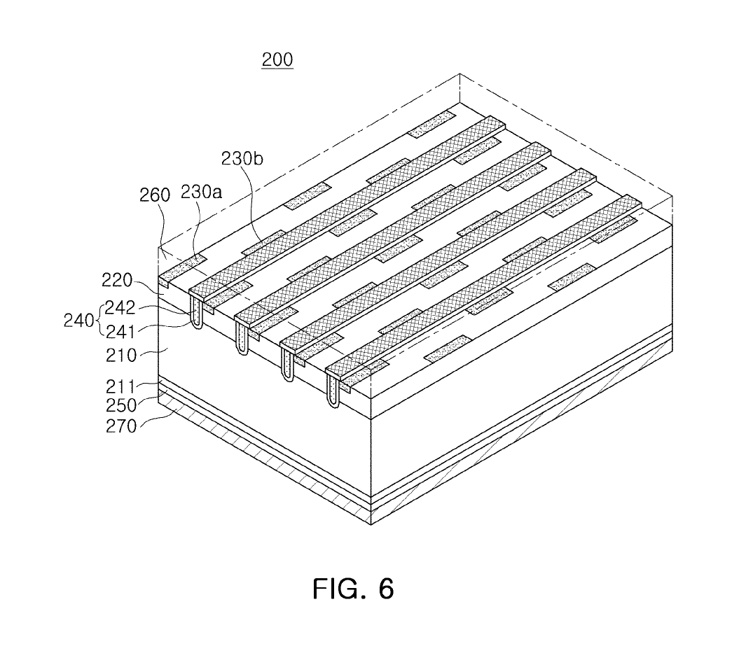

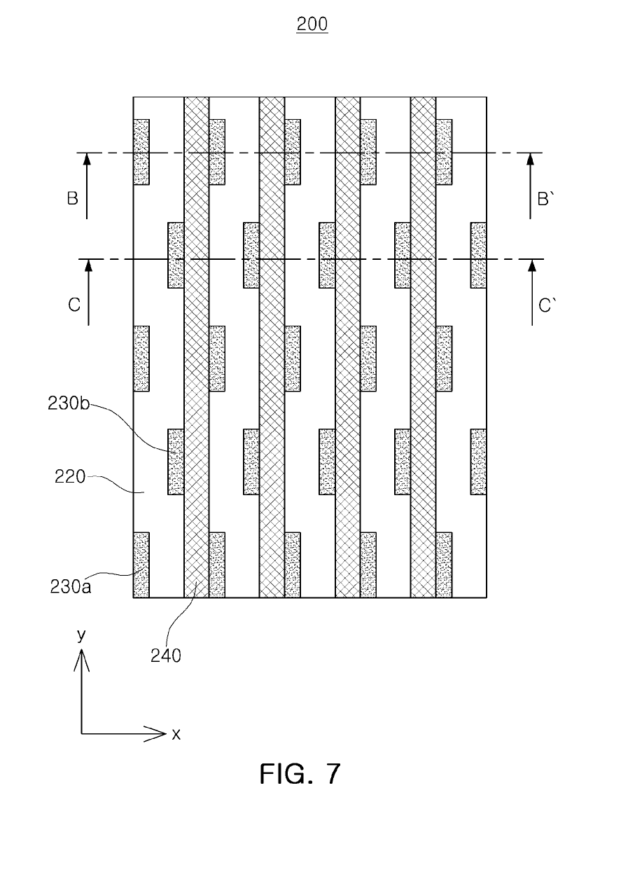

FIG. 6 schematically illustrates a perspective view of a power semiconductor device 200 according to another exemplary embodiment of the present disclosure and FIG. 7 schematically illustrates a plan view of a power semiconductor device 200 according to another exemplary embodiment of the present disclosure.

Hereinafter, a description of the configuration of the power semiconductor device 200 according to another exemplary embodiment of the present disclosure that is the same as the power semiconductor device 100 according to an exemplary embodiment of the present disclosure will be omitted.

The power semiconductor device 200 according to another exemplary embodiment of the present disclosure may include a first emitter region 230 formed at least partially in a length direction between a plurality of trench gates 240, formed to contact one side of the adjacent trench gate 240 in a width direction and to alternately contact both sides of the trench gate 240 in the length direction.

That is, the power semiconductor device 200 according to another exemplary embodiment of the present disclosure may include a plurality of trench gates 240 lengthily formed in one direction, a p-type body region 220 formed between the trench gates 240, and a plurality of n-type first emitter regions 230 formed on the body region 220 and formed to alternately contact the adjacent trench gate 240 in the length direction.

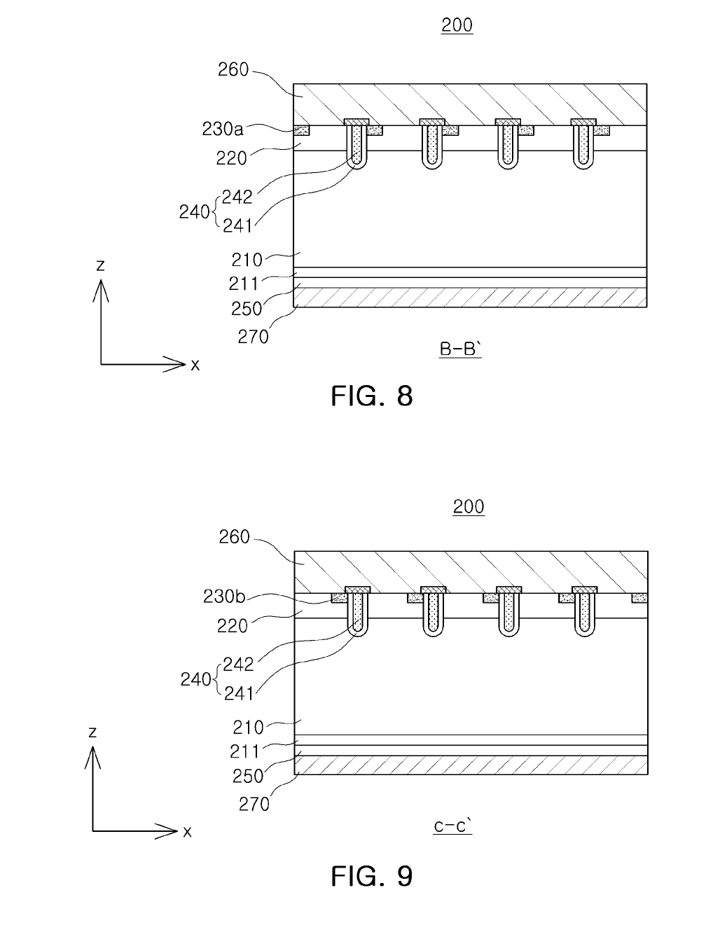

A structure of the power semiconductor device 200 according to another exemplary embodiment of the present disclosure will be described in more detail with reference to FIGS. 8 and 9, illustrating the cross-sectional view taken along a line B-B′ of FIG. 7 and the cross-sectional view taken along a line C-C′ of FIG. 7, respectively.

Referring to the cross-sectional view taken along a line B-B′ of FIG. 7, it may be seen that the first emitter region 230 is formed to contact the trench gate 240 located at the left side.

In addition, referring to the cross-sectional view taken along a line C-C′ of FIG. 7 located to be adjacent below a line B-B′ in the length direction, it may be seen that the first emitter region 230 is formed to contact the trench gate 240 located at the right side.

An area of the first emitter region 230 may be closely related to an active region in which the current may flow.

That is, when the area of the first emitter region 230 is increased, the active region in which the current may flow is also increased.

However, in the case in which the area of the first emitter region 230 is increased excessively and the first emitter regions are densely located, the blocking voltage of the power semiconductor device may be decreased.

Therefore, in the case in which the first emitter region 230 is formed to alternately contact different trench gates 240 in the length direction similar to the power semiconductor device 200 according to another exemplary embodiment of the present disclosure, the blocking voltage may be increased.

As a result, the power semiconductor device 200 according to another exemplary embodiment of the present disclosure may increase the blocking voltage and decrease the noise of the power semiconductor device 200.

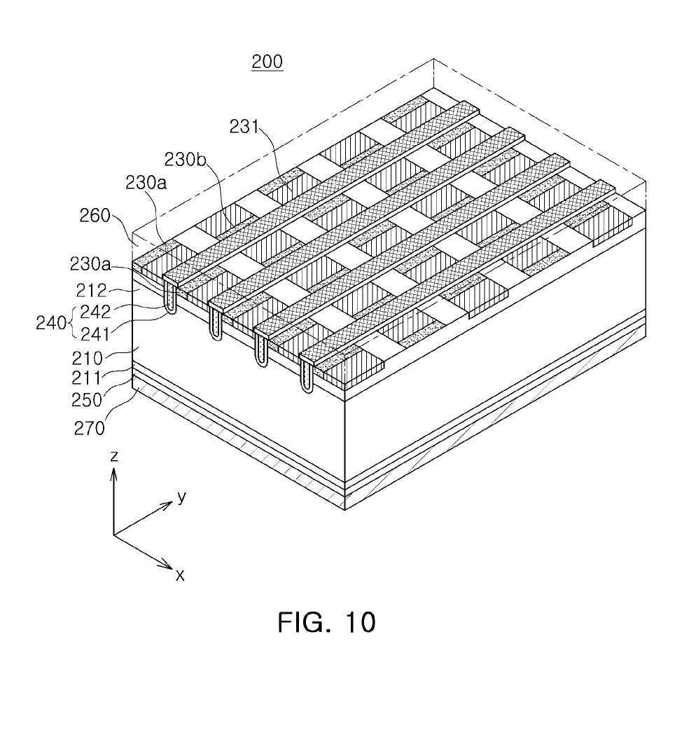

FIG. 10 schematically illustrates a perspective view of a power semiconductor device 200 according to another exemplary embodiment of the present disclosure, further including a second emitter region 231.

The power semiconductor device according to an exemplary embodiment of the present disclosure may include a parasitic thyristor having a p-n-p-n structure from the bottom.

Once the parasitic thyristor is operated, the IGBT is no longer adjusted by the gate and a significant amount of current flows into the anode and the cathode, whereby excessive heat may be generated from the device and burn the device

A phenomenon in which the parasitic thyristor is turned on is referred to as a latch-up.

Specifically describing a principle in which the latch-up occurs, when the power semiconductor device is operated, the electron current may flow along the channel and the hole current may overpass a junction surface of the body region 220, thereby flowing into a first emitter metal layer 260.

Since the electron current is injected into the drift region 210 of a lower portion of the trench gate 240 along the channel to thereby increase conductivity of the drift region 210, most of hole current may be injected from the body region 220 of a lower portion of the channel and flow into the emitter metal layer 260 through a lower portion of the first emitter region 230.

In the case in which the hole current is increased and a voltage drop across the lower portion of the first emitter region 230 becomes larger than a potential barrier of an interface between the first emitter region 230 and the body region 220, a junction becomes a forward bias, whereby the electrons may be injected from the first emitter region 230 to the body region 220 and a parasitic n-p-n thyristor including an n-type first emitter region 230, a p-type body region 220, and an n-type drift region 210 may be operated.

Therefore, it is necessary to prevent the hole current from being increased at the lower portion of the first emitter region 230.

Referring to FIG. 4, the power semiconductor device 200 according to an exemplary embodiment of the present disclosure may include a p+ type second emitter region 231.

The second emitter region 231 may be formed by injecting a high concentration p-type impurity.

The second emitter region 231 may be at least partially formed in a length direction between a plurality of trench gates 240 and be formed to contact one side of an adjacent trench gate 240 in a width direction.

In addition, the second emitter region 231 may be formed to contact a trench gate 240 opposing the trench gate 240 having the first emitter region 230 formed thereon in the width direction.

That is, the second emitter region 231 may be formed on the body region 220 and be formed to contact a trench gate 240 different from the trench gate 240 having the first emitter region 230 formed thereon in the width direction.

Since the second emitter region 231 is formed by using the high concentration p-type impurity, it may have a very low resistance against the hole current.

Therefore, the hole may flow into the second emitter region 231 and be discharged to the emitter metal layer 260.

That is, the second emitter region 230 may prevent the parasitic thyristor from being operated by preventing the hole from being overpassed to the first emitter region 230.

Therefore, in the case in which the second emitter region 231 is formed, reliability of the power semiconductor device 200 may be improved.

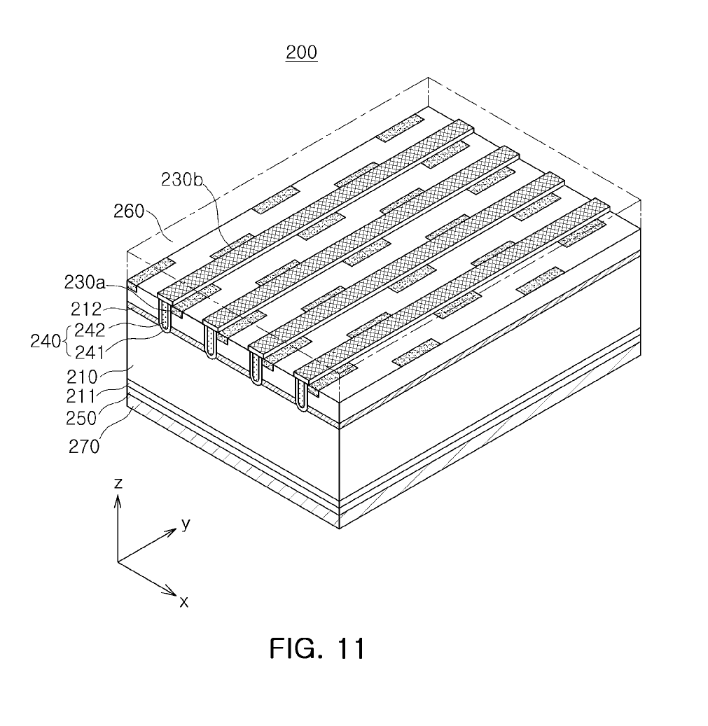

FIG. 11 schematically illustrates a perspective view of a power semiconductor device according to another exemplary embodiment of the present disclosure, further including a hole accumulation region.

The hole accumulation region 212 may be formed by injecting a high concentration n-type impurity.

In the case in which the hole accumulation region 212 is formed, since the hole is accumulated to thereby significantly increase the conductivity modulation phenomenon, the conduction loss may be decreased.

However, in the case in which only the hole accumulation region 212 is formed, an amount of accumulated holes is increased, such that the negative gate current may be increased to thereby increase the noise.

Since the power semiconductor device 200 according to an exemplary embodiment of the present disclosure includes the first emitter region 230 formed to contact one side of the trench gate 240 in the width direction, the electrons may serve as a protection film preventing the holes from affecting the trench gate 240.

That is, the power semiconductor device 200 according to an exemplary embodiment of the present disclosure may significantly decrease the effect of the holes on the trench gate 240 by significantly decreasing a portion in which the first emitter region 230 is not formed in the length direction.

Therefore, the power semiconductor device 200 according to an exemplary embodiment of the present disclosure may decrease the conduction loss through the hole accumulation region 212 and prevent the current oscillation to thereby decrease the noise of the power semiconductor device 200.

As set forth above, according to exemplary embodiments of the present disclosure, since the power semiconductor device has the n-type emitter region formed between the trench gates and formed to contact one side of both sides of the trench gate, the density of the channel may be maintained and the level of the backward gate current may be decreased.

Therefore, the power semiconductor device according to an exemplary embodiment of the present disclosure may alleviate the current oscillation, whereby the switching noise may be decreased.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a first semiconductor region of a first conductive type;
a second semiconductor region of a second conductive type disposed on the first semiconductor region;
a plurality of trench gates disposed to penetrate through the second semiconductor region and lengthily formed in one direction; and
a third semiconductor region of the first conductive type disposed in the second semiconductor region, disposed at least partially in a length direction between the plurality of trench gates, and disposed to contact one side of an adjacent trench gate in a width direction.

2. The power semiconductor device of claim 1, further comprising a fourth semiconductor region of the second conductive type disposed on the second semiconductor region, disposed at least partially in the length direction between the plurality of trench gates, disposed to contact one side of the adjacent trench gate in the width direction, and disposed on a trench gate opposing the trench gate having the third semiconductor region formed thereon in the width direction.

3. The power semiconductor device of claim 1, wherein a plurality of third semiconductor regions are formed in the length direction.

4. The power semiconductor device of claim 1, further comprising a fifth semiconductor region disposed between the first semiconductor region and the second semiconductor region and having an impurity concentration higher than that of the first semiconductor region.

5. A power semiconductor device, comprising:
a first semiconductor region of a first conductive type;
a second semiconductor region of a second conductive type disposed on the first semiconductor region;
a plurality of trench gates disposed to penetrate through the second semiconductor region and lengthily disposed in one direction; and
a third semiconductor region of the first conductive type disposed in the second semiconductor region,
wherein the third semiconductor region is disposed at least partially in a length direction between the plurality of trench gates, disposed to contact one side of an adjacent trench gate in a width direction, and disposed to alternately contact both sides of the trench gate in the length direction.

6. The power semiconductor device of claim 5, further comprising a fourth semiconductor region of the second conductive type disposed on the second semiconductor region, disposed at least partially in the length direction between the plurality of trench gates, disposed to contact one side of the adjacent trench gate in the width direction, and disposed on a trench gate opposing the trench gate having the third semiconductor region disposed thereon in the width direction.

7. A power semiconductor device, comprising:
a plurality of trench gates lengthily disposed in one direction;
a p-type body region disposed between the trench gates; and
an n-type first emitter region disposed on the body region and disposed to contact one side of an adjacent trench gate.

8. The power semiconductor device of claim 7, further comprising a p-type second emitter region disposed on the body region and disposed to contact a trench gate different from the trench gate contacting the first emitter region in a width direction.

9. A power semiconductor device, comprising:
a plurality of trench gates lengthily disposed in one direction;
a p-type body region disposed between the trench gates; and
a plurality of n-type first emitter regions disposed on the body region and disposed to alternately contact an adjacent trench gate in a length direction.

10. The power semiconductor device of claim 9, further comprising a p-type second emitter region formed on the body region and formed to contact a trench gate different from the trench gate contacting the first emitter region in a width direction.
